(19) United States
(12) Patent Application Publication
(10) Pub. No.: US 2011/0305119 A1
(43) Pub. Date: Dec. 15, 2011

(54) PACKAGE MANUFACTURING METHOD, PIEZOELECTRIC VIBRATOR MANUFACTURING METHOD, OSCILLATOR, ELECTRONIC DEVICE AND RADIO TIMEPIECE

(76) Inventors: Masashi NUMATA, Chiba-shi (JP); Kazuyoshi SUGAMA, Chiba-shi (JP); Hiroshi HIGUCHI, Yotsukaichi-shi (JP)

(21) Appl. No.: 13/215,734

(22) Filed: Aug. 23, 2011

Related U.S. Application Data
(63) Continuation of application No. PCT/JP2010/052456, filed on Feb. 18, 2010.

(30) Foreign Application Priority Data
Feb. 25, 2009 (JP) PCT/JP2009/053328

(51) Int. Cl. G04C 11/02; H01L 41/22; H03B 5/36

(52) U.S. Cl. 368/47; 331/158; 29/825; 29/25.35

(57) ABSTRACT

Provided is a manufacturing method of a package including a plurality of substrates that are bonded to each other, a cavity that is formed inside the plurality of substrates, and through electrodes that conduct current between the inside of the cavity and the outside of the plurality of substrates. The through electrodes are each formed such that a conductive core portion made of a metal material is arranged in a hole portion of a through electrode forming substrate made of a glass material. The manufacturing method includes: a hole portion forming step of forming the hole portion, into which the core portion is inserted, in a through electrode forming substrate wafer; a core portion inserting step of inserting the core portion into the hole portion formed in the through electrode forming substrate wafer; a welding step of heating the through electrode forming substrate wafer and welding it to the core portion; and a cooling step of cooling the through electrode forming substrate wafer. In the welding step, the through electrode forming substrate wafer is welded to the core portion by heating the through electrode forming substrate wafer to a temperature higher than a softening point of the glass material while a pressurizing die is placed on a surface of the through electrode forming substrate wafer and the through electrode forming substrate wafer is pressed by the pressurizing die.

### RELATED APPLICATIONS

This application is a continuation of PCT/JP2010/052456 filed on Feb. 18, 2010, which claims priority to PCT/JP2009/053328 filed on Feb. 25, 2009. The entire contents of these applications are incorporated herein by reference.

### BACKGROUND OF THE INVENTION

1. Field of the Invention

The present invention relates to: a manufacturing method of a package including a plurality of substrates that are bonded to each other, a cavity that is formed inside the plurality of substrates, and through electrodes that conduct current between the inside of the cavity and the outside of the plurality of substrates; a piezoelectric vibrator in which a piezoelectric vibrating reed is mounted on the through electrodes and is disposed inside the cavity; an oscillator having the piezoelectric vibrator; an electronic device; and a radio timepiece.

2. Description of the Related Art

In recent years, mobile telephones and portable information terminal devices employ a piezoelectric vibrator that uses crystal or the like as a time source, a timing source of control signals or the like, and a reference signal source, etc. Various examples of this type of piezoelectric vibrator are known. One known example is a surface mount type piezoelectric vibrator. As this type of piezoelectric vibrator, a three-layer structure type piezoelectric vibrator is generally known in which a piezoelectric substrate formed with a piezoelectric vibrating reed is bonded to be sandwiched from above and below by a base substrate and a lid substrate. In this case, the piezoelectric vibrating reed is housed in a cavity (a sealed chamber) formed between the base substrate and the lid substrate.

In recent years, not only the above-described three-layer structure type piezoelectric vibrator, but also a two-layer structure type piezoelectric vibrator has been developed. In this type of piezoelectric vibrator, a package has a two-layer structure in which a base substrate and a lid substrate are directly bonded to each other, and a piezoelectric vibrating reed is housed in a cavity formed between the two substrates. The two-layer structure type piezoelectric vibrator is excellent in that it can be made thinner as compared with the piezoelectric vibrator having the three-layer structure, and is therefore preferably used.

As one example of a package of the two-layer structure type piezoelectric vibrator formed in this manner, a package is known in which through electrodes are formed such that a conductive member, such as a silver paste, is filled and fired in each through hole formed in a base substrate made of glass, and a crystal oscillator and external electrodes provided on the outside of the base substrate are electrically connected (refer to Patent Document 1, for example). Patent Document 1: JP-A-2002-124845

However, the volume of the through electrode formed by the silver paste reduces when organic material, such as resin in the silver paste, is removed by firing. Therefore, there are cases in which a recessed portion is generated in the surface of the through electrode or a hole is opened in the through electrode. Then, there are cases in which the recessed portion or hole of the through electrode causes deterioration of airtightness in the cavity or degradation of conductivity between the piezoelectric vibrating reed and the external electrodes.

To address this, recently, a method has been developed in which a through electrode is formed using a metal pin made of a metal material. With this method, first, the metal pin is inserted into a through hole formed in a through electrode forming wafer, a glass frit is filled into the through hole, and the glass frit is fired so that a base substrate wafer and the metal pin are integrated. Since the metal pin is used for the through electrode, it is possible to ensure stable conductivity.

However, since an organic binder contained in the glass frit is removed by firing, there are cases in which a recessed portion is generated in the surface of the glass frit due to volume reduction. Then, there are cases in which the recessed portion of the glass frit causes disconnection in an electrode film forming process, which is performed at a later stage.

### SUMMARY OF THE INVENTION

The invention has been made in light of the above-described problems, and it is an object to provide a package manufacturing method that is capable of inhibiting generation of a recessed portion around a through electrode.

In order to solve the above-described problems, the invention has adopted the following means.

More specifically, a package manufacturing method according to the invention is a manufacturing method of a package including a plurality of substrates that are bonded to each other, a cavity that is formed inside the plurality of substrates, and through electrodes that conduct current between the inside of the cavity and the outside of the plurality of substrates. The through electrodes are each formed such that a conductive core portion made of a metal material is arranged in a hole portion of a through electrode forming substrate made of a glass material. The manufacturing method includes: a hole portion forming step of forming the hole portion, into which the core portion is inserted, in a through electrode forming substrate wafer; a core portion inserting step of inserting the core portion into the hole portion formed in the through electrode forming substrate wafer; a welding step of heating the through electrode forming substrate wafer and welding it to the core portion; and a cooling step of cooling the through electrode forming substrate wafer. In the welding step, the through electrode forming substrate wafer is welded to the core portion by heating the through electrode forming substrate wafer to a temperature higher than a softening point of the glass material while a pressurizing die is placed on a surface of the through electrode forming substrate wafer and the through electrode forming substrate wafer is pressed by the pressurizing die.

In the invention, it is possible to form the through electrodes using a material that does not include an organic binder because the through electrode forming substrate wafer is welded to the core portion by heating the through electrode forming substrate wafer while the through electrode forming substrate wafer and the core portion are pressed by the pressurizing die. Therefore, there is no volume reduction resulting from the removal of organic material, and it is possible to inhibit generation of a recessed portion around each of the through electrodes.

Further, the package manufacturing method according to the invention is characterized in that, in the cooling step, a cooling rate from a strain point of the glass material that forms the through electrode forming substrate wafer plus 50° C. to the strain point minus 50° C. is made slower than a cooling rate from a heating temperature of the welding step to the strain point plus 50° C.

In the invention, the cooling rate from the strain point of the glass material that forms the through electrode forming substrate wafer plus 50° C. to the strain point minus 50° C. is made slower than the cooling rate from the heating temperature of the welding step to the strain point plus 50° C. In the welding step, the through electrode forming substrate wafer is heated to the softening point that is higher than the strain point. Therefore, if rapid cooling is performed in the cooling step, there is a possibility that strain remains in the through electrode forming substrate wafer. To address this, by reducing the cooling rate in a range of plus/minus 50° C. of the strain point, it is possible to inhibit generation of strain in the through electrode forming substrate wafer.

Further, the package manufacturing method according to the invention is characterized in that, in the hole portion forming step, a through hole is formed as the hole portion, the pressurizing die has a recessed portion into which an upper end of the core portion can be inserted, and a bottom of the recessed portion is formed to be separated from the upper end of the core portion when the through electrode forming substrate wafer is pressed by the pressurizing die.

In the invention, the bottom of the pressurizing die is formed to be separated from the upper end of the core portion when the through electrode forming substrate wafer is pressed by the pressurizing die. Therefore, it is possible to relieve expansion of the core portion due to heating. In addition, when being pressed, no pressure is applied from the pressurizing die to the core portion, and it is possible to inhibit generation of a crack or chip in the through hole forming substrate wafer due to deformation or displacement of the core portion.

Further, the package manufacturing method according to the invention is characterized in that the pressurizing die is formed of a material whose main component is one of carbon, aluminium oxide, zirconia, boron nitride and silicon nitride.

In the invention, since the pressurizing die is formed of a material whose main component is one of carbon, aluminium oxide, zirconia, boron nitride and silicon nitride, it is possible to suppress deformation of the pressurizing die due to high temperature. At the same time, die releasing of the pressurizing die from the through electrode forming substrate wafer is easy and work efficiency is good.

Further, the package manufacturing method according to the invention is characterized in that, in the hole portion forming step, the hole portion is formed by heating the through electrode forming substrate wafer while the through electrode forming substrate wafer is pressed by a hole portion forming die that is made of a carbon material and that has a protruding portion corresponding to the hole portion.

In the invention, since the hole portion is formed using the hole portion forming die, the hole portion can be formed easily and precisely. Further, since the hole portion forming die is formed by a carbon material, the softened glass material of the through electrode forming substrate wafer does not adhere to the hole portion forming die, and the hardened through electrode forming substrate wafer is easily removed from the hole portion forming die, achieving high work efficiency. Moreover, when the through electrode forming substrate wafer is heated while the through electrode forming substrate wafer is pressed by the hole portion forming die, the hole portion forming die adsorbs gas generated from the through electrode forming substrate wafer and it is possible to inhibit generation of pores in the through electrode forming substrate wafer. Therefore, it is possible to maintain airtightness in the cavity.

Further, the package manufacturing method according to the invention is characterized in that, in the core portion inserting step, the core portion of a conductive rivet, which has a flat plate-shaped base portion and the core portion that stands on a surface of the base portion, is inserted into the hole portion formed in the through electrode forming substrate wafer, and the base portion of the rivet is caused to come into contact with the through electrode forming substrate wafer. After the cooling step, the base portion of the rivet is polished and removed.

In the invention, since the core portion of the conductive rivet, which has the flat plate-shaped base portion and the core portion that stands on the surface of the base portion, is inserted into the hole portion, the core portion is easily disposed in the hole portion and work efficiency is good.

Further, the package manufacturing method according to the invention is characterized in that the core portion is formed in a truncated cone shape, and in the hole portion forming step, an inner peripheral surface of the hole portion is formed in a tapered shape.

In the invention, since the core portion is formed in a truncated cone shape and the inner peripheral surface of the hole portion is formed in a tapered shape, the core portion is easily disposed in the hole portion in the core portion inserting step and work efficiency is good.

Further, the package manufacturing method according to the invention is characterized in that, in the hole portion forming step, the hole portion is formed in the through electrode forming substrate wafer as a recessed portion, and after the cooling step, the through electrode forming substrate wafer on a bottom side of the recessed portion is polished and the core portion is exposed.

In the invention, since the recessed portion is formed in the through electrode forming substrate wafer in the hole portion forming step, a longer die life is obtained for a protruding portion of the hole portion forming die, as compared with a case in which a through hole is formed in the through electrode forming substrate wafer in the hole forming step.

Further, a piezoelectric vibrator manufacturing method according to the invention is characterized by including the steps of: performing one of the above-described package manufacturing methods; and disposing a piezoelectric vibrating reed inside the cavity while the piezoelectric vibrating reed is mounted on the through electrodes.

In the invention, since it is possible to inhibit generation of recessed portions around the through electrodes, it is possible to ensure conductivity between the piezoelectric vibrating reed and the through electrodes. Further, since the through electrode forming substrate wafer is welded to the core portion, it is possible to ensure airtightness in the cavity. As a result, the piezoelectric vibrator with high reliability can be provided.

An oscillator according to the invention is characterized in that a piezoelectric vibrator manufactured by the above-described method is electrically connected to an integrated circuit, as an oscillation element.

An electronic device according to the invention is characterized in that a piezoelectric vibrator manufactured by the above-described method is electrically connected to a time measuring portion.

A radio timepiece according to the invention is characterized in that a piezoelectric vibrator manufactured by the above-described method is electrically connected to a filter portion.

The oscillator, the electronic device and the radio timepiece according to the invention use the piezoelectric vibrator in which conductivity between the piezoelectric vibrating reed and the through electrodes is stably ensured. Therefore, the oscillator, the electronic device and the radio timepiece that have high reliability can be provided.

According to the invention, the through electrode forming substrate wafer is welded to the core portion by heating the through electrode forming substrate wafer while it is pressed by the pressurizing die. Therefore, it is possible to inhibit recessed portions, which could cause disconnection in an electrode film forming step, from being generated around the through electrodes. Further, it is possible to ensure stable conductivity between the piezoelectric vibrating reed and external electrodes, and it is also possible to ensure stable airtightness in the cavity of the piezoelectric vibrator. Therefore, uniform performance of the piezoelectric vibrator can be achieved.

### BRIEF DESCRIPTION OF THE DRAWINGS

FIG. 1 is an external perspective view showing an example of a piezoelectric vibrator according to a first embodiment of the invention.

FIG. 2A is a cross-sectional view taken along a line A-A in FIG. 2B.

FIG. 2B is a cross-sectional view taken along a line B-B in FIG. 2A.

FIG. 3 is a perspective view of a rivet that is used when the piezoelectric vibrator shown in FIG. 1 is manufactured.

FIG. 4 is a flowchart showing a manufacturing flow of the piezoelectric vibrator shown in FIG. 1.

FIG. 5 is a perspective view showing a state in which through holes are formed in a base substrate wafer, which becomes a base substrate that is provided in the piezoelectric vibrator shown in FIG. 1.

FIG. 6A is a view illustrating a through hole forming process of the flowchart shown in FIG. 4, and is a view showing a through hole forming die and the base substrate wafer.

FIG. 6B is a view illustrating the through hole forming process of the flowchart shown in FIG. 4, and is a view showing a state in which the through hole forming die is used to form the through holes in the base substrate wafer.

FIG. 7A is a view illustrating a core portion inserting process of the flowchart shown in FIG. 4.

FIG. 7B is a view illustrating a welding process of the flowchart shown in FIG. 4.

FIG. 7C is a view illustrating a polishing process of the flowchart shown in FIG. 4, and is a view showing a state before the polishing process.

FIG. 7D is a view illustrating the polishing process of the flowchart shown in FIG. 4, and is a view showing a state after the polishing process.

FIG. 8 is a view showing an example of a piezoelectric vibrator according to a second embodiment of the invention.

FIG. 9 is a perspective view of a rivet that is used when the piezoelectric vibrator shown in FIG. 8 is manufactured.

FIG. 10 is a flowchart showing a manufacturing flow of the piezoelectric vibrator shown in FIG. 8.

FIG. 11A is a view illustrating a through hole forming process of the flowchart shown in FIG. 8, and is a view showing a through hole forming die and the base substrate wafer.

FIG. 11B is a view illustrating the through hole forming process of the flowchart shown in FIG. 8, and is a view showing a state in which the through hole forming die is used to form through holes in the base substrate wafer.

FIG. 12A is a view illustrating a core portion inserting process of the flowchart shown in FIG. 8.

FIG. 12B is a view illustrating a welding process of the flowchart shown in FIG. 8.

FIG. 12C is a view illustrating a polishing process of the flowchart shown in FIG. 8, and is a view showing a state before the polishing process.

FIG. 12D is a view illustrating the polishing process of the flowchart shown in FIG. 8, and is a view showing a state after the polishing process.

FIG. 13A is an explanatory view of a welding process according to a modified example of the first embodiment.

FIG. 13B is a view illustrating a polishing process according to the modified example of the first embodiment, and is a view showing a state before the polishing process.

FIG. 13C is a view illustrating the polishing process according to the modified example of the first embodiment, and is a view showing a state after the polishing process.

FIG. 14 is a view illustrating a core portion inserting process and a welding process according to a modified example of the second embodiment.

FIG. 15 is a view illustrating a core portion inserting process and a welding process according to another modified example of the second embodiment.

FIG. 16 is a structural view showing one embodiment of an oscillator according to the invention.

FIG. 17 is a structural view showing one embodiment of an electronic device according to the invention.

FIG. 18 is a structural view showing one embodiment of a radio timepiece according to the invention.

### DETAILED DESCRIPTION OF THE PREFERRED EMBODIMENTS

### First Embodiment

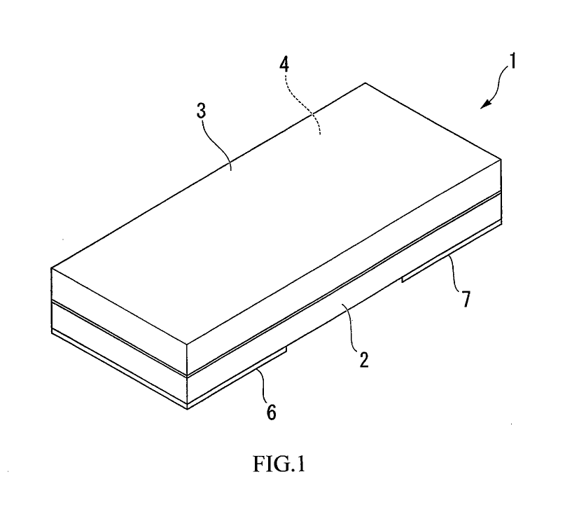

Hereinafter, a package manufacturing method according to a first embodiment of the invention will be described based on FIG. 1 to FIG. 7D.

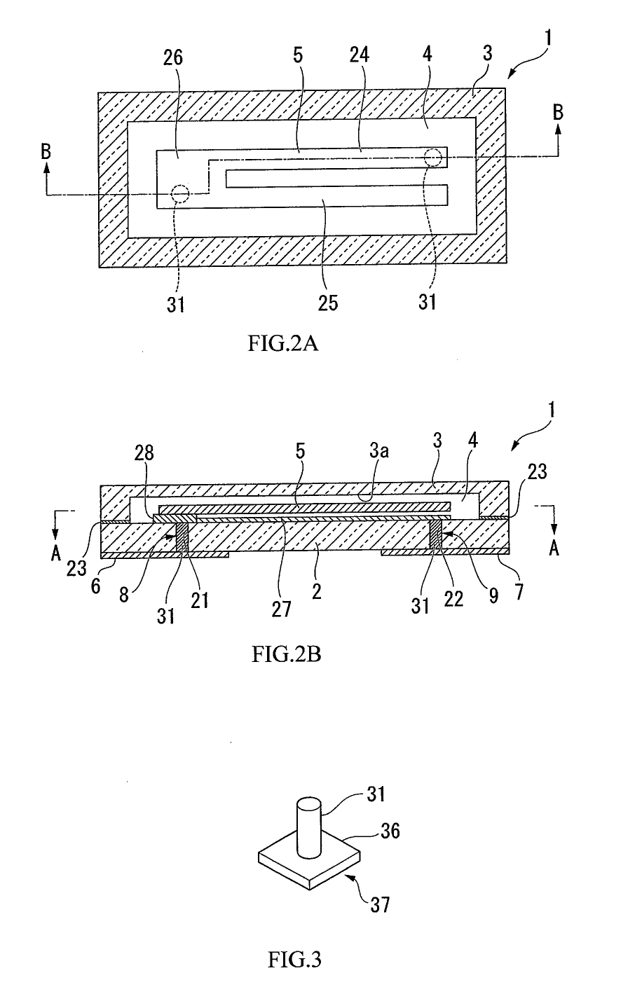

As shown in FIG. 1, FIG. 2A and FIG. 2B, a piezoelectric vibrator 1 according to the first embodiment is formed in a box shape such that a base substrate 2 and a lid substrate 3 are laminated in two layers, and is the surface mount type piezoelectric vibrator 1 in which a piezoelectric vibrating reed 5 is housed in an internal cavity 4. The piezoelectric vibrating reed 5 and external electrodes 6, 7 that are arranged on the outside of the base substrate 2 are electrically connected by a pair of through electrodes 8, 9 that penetrate the base substrate 2.

The base substrate 2 is a transparent insulating substrate made of a glass material, such as soda lime glass for example, and is formed in a plate shape. A pair of through holes 21, 22, in which the pair of through electrodes 8, 9 are formed, are formed in the base substrate 2.

Similarly to the base substrate 2, the lid substrate 3 is a transparent insulating substrate made of a glass material, such as soda lime glass for example, and is formed in a plate shape having a size that can be overlapped and aligned with the base substrate 2. A rectangular-shaped recessed portion 3a, in which the piezoelectric vibrating reed 5 is housed, is formed on a bonding surface side of the lid substrate 3 to which the base substrate 2 is bonded.

When the base substrate 2 and the lid substrate 3 are overlapped with each other, the recessed portion 3a forms the cavity 4 that houses the piezoelectric vibrating reed 5. The lid substrate 3 is anodically bonded to the base substrate 2 via a bonding material 23 in a state in which the recessed portion 3a faces the base substrate 2 side.

The piezoelectric vibrating reed 5 is a tuning-fork type vibrating reed formed of a piezoelectric material, such as crystal, lithium tantalate, lithium niobate or the like, and it vibrates when a predetermined voltage is applied.

The piezoelectric vibrating reed 5 has a general U-shape in a plan view, and is formed by a pair of vibrating arm portions 24, 25 that are disposed parallel to each other, and a base portion 26 that integrally fixes a base end side of the pair of vibrating arm portions 24, 25. Provided on outer surfaces of the pair of vibrating arm portions 24, 25 are: a pair of excitation electrodes formed by a first excitation electrode and a second excitation electrode (which are not shown in the drawings) that vibrate the vibrating arm portions 24, 25; and a pair of mount electrodes that are electrically connected to the first excitation electrode and the second excitation electrode.

The first excitation electrode of the piezoelectric vibrating reed 5 is electrically connected to one of the external electrodes, the external electrode 6, via one of the mount electrodes and one of the through electrodes, the through electrode 8, and the second excitation electrode of the piezoelectric vibrating reed 5 is electrically connected to the other of the external electrodes, the external electrode 7, via the other of the mount electrodes, a routing electrode 27, and the other of the through electrodes, the through electrode 9. The piezoelectric vibrating reed 5 and the mount electrodes are connected by an adhesive 28 or the like, which is a conductive material.

The external electrodes 6, 7 are provided at both ends in a longitudinal direction of a bottom surface of the base substrate 2.

The through electrodes 8, 9 are formed such that core portions 31 made of a conductive metal material are disposed in the through holes 21, 22, and stable electrical conductivity is ensured through the core portions 31.

The one of the through electrodes, the through electrode 8, is located above the external electrode 6 and below the base portion 26. The other of the through electrodes, the through electrode 9, is located above the external electrode 7 and below the routing electrode 27.

The core portions 31 are fixed by welding to a base substrate wafer 41, and the core portions 31 completely fill the through holes 21, 22 to maintain airtightness in the cavity 4.

Each of the core portions 31 is a conductive metal core that is formed in a column shape using a material, such as Kovar or Fe—Ni alloy (42 alloy) for example, having a thermal expansion coefficient that is close to (preferably, substantially the same as or lower than) that of the glass material of the base substrate 2, and both ends are flat and the thickness is the same as that of the base substrate 2.

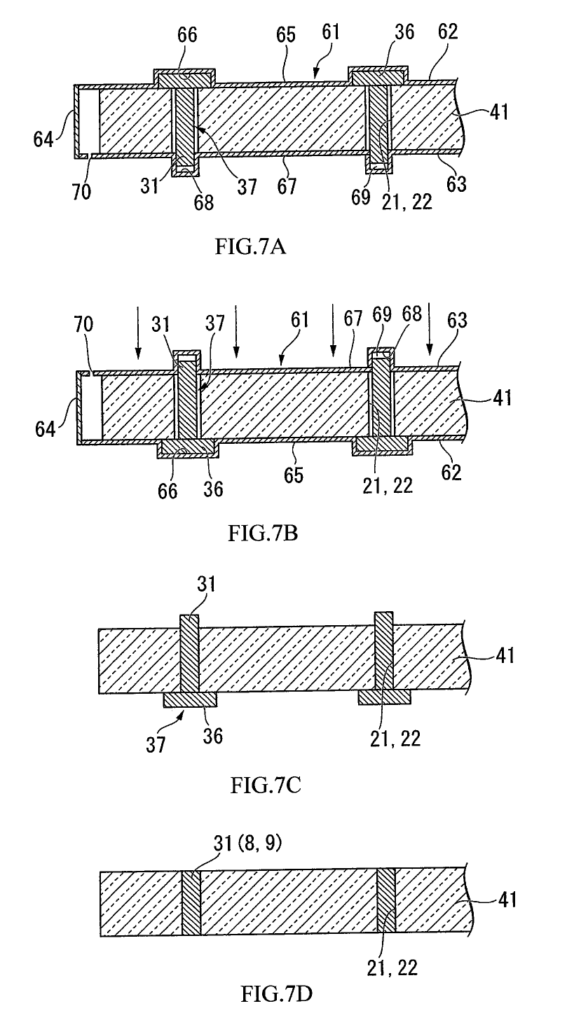

Note that, when the through electrodes 8, 9 are formed as final products, each of the core portions 31 is formed such that it has a column shape and the same thickness as that of the base substrate 2 as described above. However, in a manufacturing process, as shown in FIG. 3, the core portion 31 forms a rivet 37 together with a flat plate-shaped base portion 36 that is connected to one of the ends of the core portion 31. The thickness of the core portion 31 is larger than that of the base substrate wafer 41 that later becomes the base substrate 2. As shown in FIG. 7A, when inserted in the through holes 21, 22, tip ends of the core portions 31 protrude from a surface 41a of the base substrate wafer 41.

The base portions 36 and the tip ends of the core portions 31 that protrude from the surface 41a of the base substrate wafer 41 are polished and removed in a manufacturing process.

### (Package Manufacturing Method)

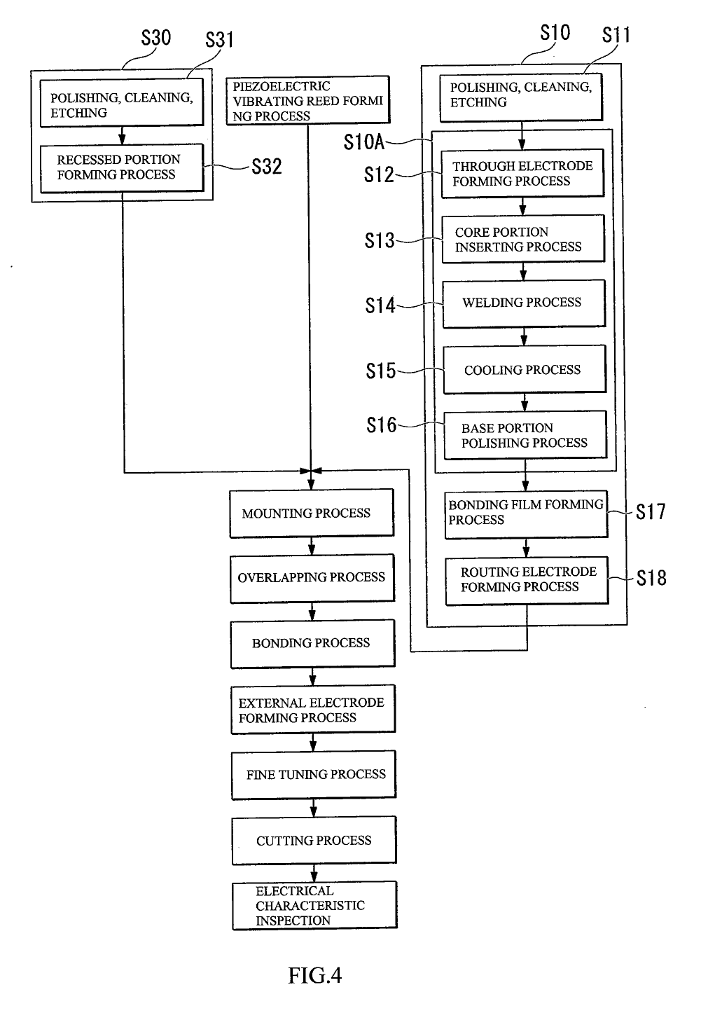

Next, a manufacturing method of a package (the piezoelectric vibrator 1) that houses the above-described piezoelectric vibrating reed will be described with reference to the flowchart shown in FIG. 4.

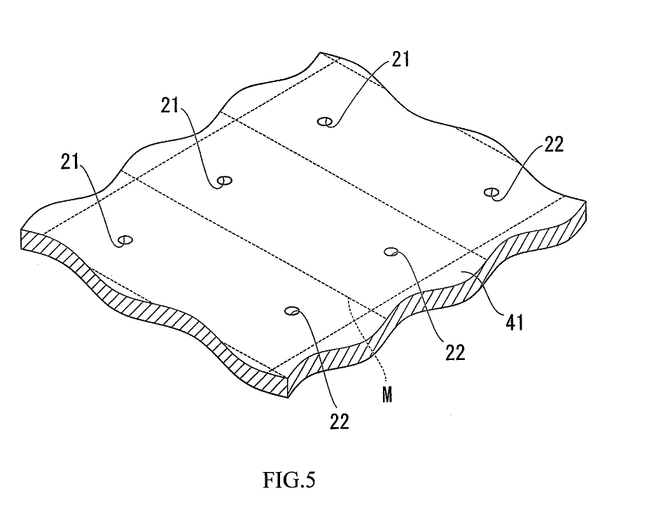

First, a process that manufactures the base substrate wafer 41, which later becomes the base substrate 2, is performed (S10). First, the base substrate wafer 41 such as that shown in FIG. 5 is formed. Specifically, after the soda lime glass is polished and processed to a predetermined thickness and then cleaned, a work-affected layer on an outermost surface is removed by etching or the like (S11).

Note that FIG. 5 shows a part of the base substrate wafer 41, and actually the base substrate wafer 41 has a disc shape. Further, dotted lines M in FIG. 5 indicate cutting lines along which the base substrate wafer 41 is cut in a later cutting process. Further, the through holes 21, 22 in FIG. 5 are formed in a process that forms the through electrodes 8, 9 in the base substrate wafer 41, which will be described below.

Next, the through electrode forming process is performed in which the through electrodes 8, 9 are formed in the base substrate wafer 41 (S10A).

### (Through Hole Forming Process)

First, the through holes (hole portions) 21, 22 that penetrate the base substrate wafer 41 are formed (S12).

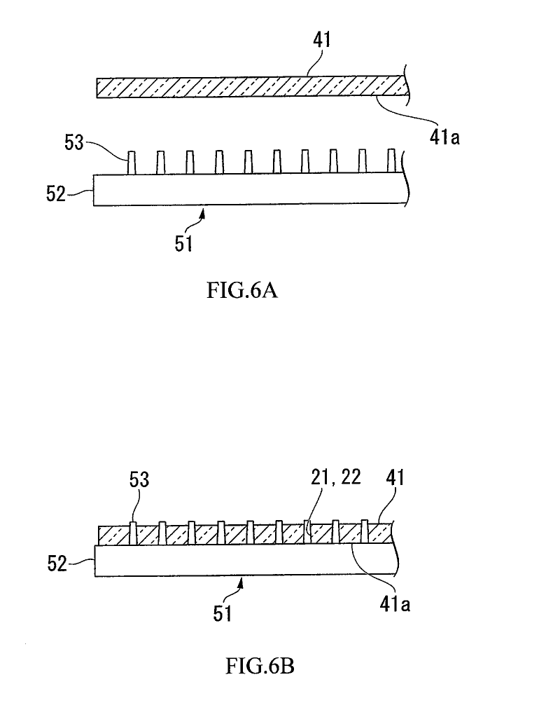

As shown in FIG. 6A and FIG. 6B, the through holes 21, 22 are formed such that the base substrate wafer 41 is heated while the base substrate wafer 41 is pressed by a through hole forming die (a hole portion forming die) 51 that is made of a carbon material and that includes a flat plate portion 52 and protruding portions 53 formed on one surface of the flat plate portion 52.

The flat plate portion 52 is a flat member that comes into contact with the surface 41a of the base substrate wafer 41 when the base substrate wafer 41 is pressed.

The protruding portions 53 are members that penetrate the base substrate wafer 41 when the base substrate wafer 41 is pressed, and thus form the through holes 21, 22. A taper for die cutting is formed on a side surface of each of the protruding portions 53, and the shape of the protruding portions 53 is transferred to the through holes 21, 22. At this time, the through holes 21, 22 are formed to have an inner diameter that is approximately 20 to 30 μm larger than the diameter of the core portions 31.

Note that the through holes 21, 22 are filled by the core portions 31 by the base substrate wafer 41 being welded to the core portions 31 in a subsequent manufacturing process.

In a through hole forming process, first, the through hole forming die 51 is placed such that the protruding portions 53 are on the upper side, and the base substrate wafer 41 is placed on the through hole forming die 51. Then, they are put in a heating furnace, and pressure is applied in a high temperature state of about 900° C. so that the base substrate wafer 41 is penetrated by the protruding portions 53.

At this time, the base substrate wafer 41 that has been heated and softened does not adhere to the flat plate portion 52 and the protruding portions 53 because the flat plate portion 52 and the protruding portions 53 are made of a carbon material. Therefore, the through hole forming die 51 can be easily removed from the base substrate wafer 41.

Further, since the flat plate portion 52 and the protruding portions 53 are made of a carbon material, they adsorb gas generated from the base substrate wafer 41 in the high temperature state, and it is possible to inhibit generation of pores in the base substrate wafer 41. Thus, it is possible to reduce the porosity of the base substrate wafer 41. This makes it possible to maintain airtightness in the cavity 4.

Note that, instead of the carbon material, the through hole forming die 51 may be formed of a material whose main component is one of aluminium oxide, zirconia, boron nitride and silicon nitride. When the through hole forming die 51 is formed of the above-described type of material, heat resistance is high, thermal deformation is small, and die releasing is easy, thus achieving high work efficiency and easy handling.

Next, the base substrate wafer 41 is cooled by gradually reducing the temperature. This cooling method will be described in detail when explaining a cooling process that is performed after a welding process.

### (Core Portion Inserting Process)

Next, a process that inserts the core portions 31 into the through holes 21, 22 is performed (S13).

As shown in FIG. 7A, the base substrate wafer 41 is placed on a pressurizing die 63 of a welding die 61 to be described later, the core portions 31 of the rivets 37 are inserted from above into the through holes 21, 22, and the base portions 36 of the rivets 37 are brought into contact with the base substrate wafer 41. The base substrate wafer 41 and the core portions 31 are sandwiched by the pressurizing die 63 and a receiving die 62 of the welding die 61 to be described later, and they are turned upside down as shown in FIG. 7B.

The process that inserts the core portions 31 into the through holes 21, 22 is performed using a nesting machine.

In this case, the base portions 36 are larger than an opening of each of the through holes 21, 22 and have a planar shape so that the opening can be sealed. Since each of the core portions 31 is connected to the base portion 36 to form the rivet 37, the core portions 31 are easily inserted into the through holes 21, 22 and work efficiency is good.

### (Welding Process)

Next, a process is performed in which the base substrate wafer 41 is heated and the base substrate wafer 41 is welded to the core portions 31 (S14).

As shown in FIG. 7B, the welding process is performed such that the base substrate wafers 41 are placed one by one on the welding die 61, and each of the base substrate wafers 41 is heated while the base substrate wafer 41 is pressed. The welding die 61 is made of a carbon material and includes the receiving die 62 that is placed below the base substrate wafer 41, the pressurizing die 63 that is placed above the base substrate wafer 41, and side plates 64 that are placed laterally with respect to the receiving die 62 and the pressurizing die 63.

Note that, instead of the carbon material, the welding die 61 may be formed of a material whose main component is one of aluminium oxide, zirconia, boron nitride and silicon nitride. When the welding die 61 is formed of the above-described type of material, heat resistance is high and thermal deformation is small. Further, die releasing is easy when removing the die, and work efficiency is good. In addition, a good surface finish of the pressurized base substrate wafer 41 is obtained.

The receiving die 62 is a die that holds the lower side of the base substrate wafer 41 and the rivets 37. It has a size larger than a planar shape of the base substrate wafer 41, and has a shape along the lower side of the base substrate wafer 41, on which the base portions 36 protrude from the surface 41a of the base substrate wafer 41 when the core portions 31 of the rivets 37 are inserted into the through holes 21, 22.

The receiving die 62 is provided with a receiving die flat plate portion 65 that comes into contact with the surface 41a of the base substrate wafer 41 when the base substrate wafer 41 is held, and receiving die recessed portions 66 that are recessed portions corresponding to the base portions 36 and that come into contact with the base portions 36.

The receiving die recessed portions 66 are formed in alignment with the positions of the base portions 36 of the rivets 37 provided in the base substrate wafer 41. The base portions 36 are fitted into the receiving die recessed portions 66 so that the receiving die 62 can hold the rivets 37, and it is possible to inhibit removal of the rivets 37 or misalignment of the core portions 31.

The pressurizing die 63 is a die that presses the base substrate wafer 41. It has the same planar shape as the receiving die 62, and has a shape along the upper side of the base substrate wafer 41, on which the tip ends of the core portions 31 protrude from the surface 41a of the base substrate wafer 41 when the core portions 31 of the rivets 37 are inserted into the through holes 21, 22.

The pressurizing die 63 is provided with a pressurizing die flat plate portion 67 that comes into contact with the surface 41a of the base substrate wafer 41 when the upper side of the base substrate wafer 41 is pressed, and pressurizing die recessed portions 68 into which the tip ends of the core portions 31 are inserted.

The pressurizing die recessed portions 68 are recessed portions having a depth that is approximately 0.2 mm larger than the height of the core portions 31 that protrude from the base substrate wafer 41, and include clearances 69 between the tip ends of the core portions 31 and bottoms of the recessed portions 68.

Since there are the clearances 69 between the tip ends of the core portions 31 and the bottoms of the recessed portions 68, it is possible to relieve expansion of the core portions 31 due to heating. Further, pressure is not applied from the pressurizing die 63 to the core portions 31 when the base substrate wafer 41 is pressed by the pressurizing die 63, and it is therefore possible to inhibit deformation or displacement of the core portions 31.

The pressurizing die recessed portions 68 are formed in alignment with the positions of the core portions 31 that protrude from the base substrate wafer 41.

Further, a slit 70 that penetrates the pressurizing die 63 is provided at an end of the pressurizing die 63. The slit 70 can be used as a relief hole for air or excess glass material of the base substrate wafer 41 when the base substrate wafer 41 is heated and pressed.

In the welding process, first, the base substrate wafer 41 and the rivets 37 set in the welding die 61 are put in the heating furnace and heated in a state in which they are placed on a metal mesh belt. Then, with the use of a pressing machine or the like disposed in the heating furnace, the base substrate wafer 41 is pressurized by the pressurizing die 63 at a pressure of 30 to 50 g/cm², for example.

The heating temperature is set to a temperature that is higher than a softening point (545° C., for example) of the glass of the base substrate wafer 41, and is set to about 900° C., for example.

The heating temperature is gradually increased and when it reaches 550° C., for example, which is 5° C. higher than the softening point of the glass, the increase is temporarily stopped and the temperature is maintained. After that, it is increased again to about 900° C. In this manner, since the temperature increase is temporarily stopped at the temperature that is 5° C. higher than the softening point of the glass and the temperature is maintained, it is possible to achieve uniform softening of the base substrate wafer 41.

Then, the base substrate wafer 41 is pressurized in the high temperature state. Thus, the base substrate wafer 41 flows to fill in clearances between the core portions 31 and the through holes 21, 22, and the base substrate wafer 41 is welded to the core portions 31, resulting in a state in which the core portions 31 fill in the through holes 21, 22.

Note that, if other protruding portions or recessed portions are formed in the welding die 61, it is also possible to weld the base substrate wafer 41 to the core portions 31 while recessed portions or protruding portions are formed on the base substrate wafer 41.

### (Cooling Process)

Next, the base substrate wafer 41 is cooled (S15).

Cooling of the base substrate wafer 41 is performed by gradually lowering the temperature from about 900° C. at the time of heating in the welding process. The cooling rate is set such that a cooling rate from the strain point of the glass that forms the base substrate wafer 41 plus 50° C. to the strain point minus 50° C. is slower than a cooling rate from about 900° C. to the strain point plus 50° C. In particular, slow cooling is performed from the annealing point to the strain point of the glass material that forms the base substrate wafer 41.

The cooling from the strain point plus 50° C. to the strain point minus 50° C. is performed by, for example, transferring the base substrate wafer 41 to another furnace.

In this manner, slow cooling is performed in a range of plus/minus 50° C. of the strain point, and it is therefore possible to inhibit generation of strain in the base substrate wafer 41. Since the thermal expansion coefficient of the glass material of the base substrate wafer 41 is different from that of the metal material of the core portions 31, if strain is generated in the base substrate wafer 41, there are cases in which clearances are generated between the through holes 21, 22 and the core portions 31 or a crack is generated in the vicinity of each of the core portions 31. By inhibiting strain of the base substrate wafer 41, it is possible to maintain a state in which the base substrate wafer 41 is reliably welded to the core portions 31.

Note that a cooling rate from the strain point minus 50° C. to a room temperature may be set to be higher than the cooling rate from the strain point plus 50° C. to the strain point minus 50° C., in order to shorten the cooling time.

In this manner, the base substrate wafer 41 is formed in which the core portions 31 of the rivets 37 fill in the through holes 21, 22 as shown in FIG. 7C.

Note that, in the through hole forming process, a method for cooling the heated base substrate wafer 41 is also performed using the above-described cooling method.

### (Polishing Process)

Next, the base portions 36 of the rivets 37 and protruding portions of the core portions 31 are polished and removed (S16).

The polishing of the base portions 36 and the core portions 31 of the rivets 37 is performed using a known method. Then, as shown in FIG. 7D, the surface 41a of the base substrate wafer 41 and the surfaces of the through electrodes 8, 9 (the core portions 31) are made substantially flush with each other. In this manner, the through electrodes 8, 9 are formed in the base substrate wafer 41.

Note that the base portions 36 and the protruding portions of the core portions 31 may be used as they are, without removing them. For example, the base portions 36 and the protruding portions of the core portions 31 can be used as radiator plates.

Next, a bonding film forming process is performed in which a conductive material is patterned onto an upper surface of the base substrate wafer 41 and a bonding film is thereby formed (S17). At the same time, a routing electrode forming process is performed (S18).

In this way, the manufacturing process of the base substrate wafer 41 ends.

Next, concurrently with the manufacture of the base substrate 2, or at a timing before or after it, a lid substrate wafer, which later becomes the lid substrate 3, is manufactured (S30). In a process that manufactures the lid substrate 3, first, the disc-shaped lid substrate wafer, which later becomes the lid substrate 3, is formed. Specifically, after the soda lime glass is polished and processed to a predetermined thickness and then cleaned, a work-affected layer on an outermost surface is removed by etching or the like (S31). Next, the recessed portion 3a for the cavity 4 is formed in the lid substrate wafer by etching, press working or the like (S32).

Then, the piezoelectric vibrating reed 5 is disposed in the cavity 4, which is formed by the base substrate wafer 41 and the lid substrate wafer that are formed in this way, and is thereby mounted on the through electrodes 8, 9. The base substrate wafer 41 and the lid substrate wafer are anodically bonded together to form a wafer body.

Then, the pair of external electrodes 6, 7 that are electrically connected to the pair of through electrodes 8, 9, respectively, are formed and the frequency of the piezoelectric vibrator 1 is fine tuned. Then, the wafer body is cut into small pieces and an inspection of internal electrical characteristics is performed, thereby forming the package (the piezoelectric vibrator 1) that houses the piezoelectric vibrating reed 5.

With the package manufacturing method of the piezoelectric vibrator according to the above-described first embodiment, in the process that forms the through electrodes 8, 9 in the base substrate wafer 41, while the base substrate wafer 41, in which the core portions 31 of the rivets 37 are inserted in the through holes 21, 22, is held by the receiving die 62, the base substrate wafer 41 is heated to a temperature higher than the softening point of the glass material and is pressed by the pressurizing die 63. Thus, the base substrate wafer 41 is welded to the core portions 31 and the through electrodes 8, 9 are thereby formed. Further, since no organic material is included in the material used to form the through electrodes 8, 9, there is no volume reduction resulting from the removal of organic material, and it is possible to inhibit generation of recessed portions around the through electrodes 8, 9.

Further, with the package manufacturing method of the piezoelectric vibrator according to the embodiment, since the recessed portions that could cause disconnection in an electrode film forming process are not generated around the through electrodes 8, 9, it is possible to ensure stable conductivity between the piezoelectric vibrating reed 5 and the external electrodes 6, 7. Further, since the base substrate wafer 41 can be welded to the core portions 31, it is also possible to ensure stable airtightness in the cavity 4 of the piezoelectric vibrator 1, thereby achieving an advantageous effect of uniform performance of the piezoelectric vibrator 1.

### Second Embodiment

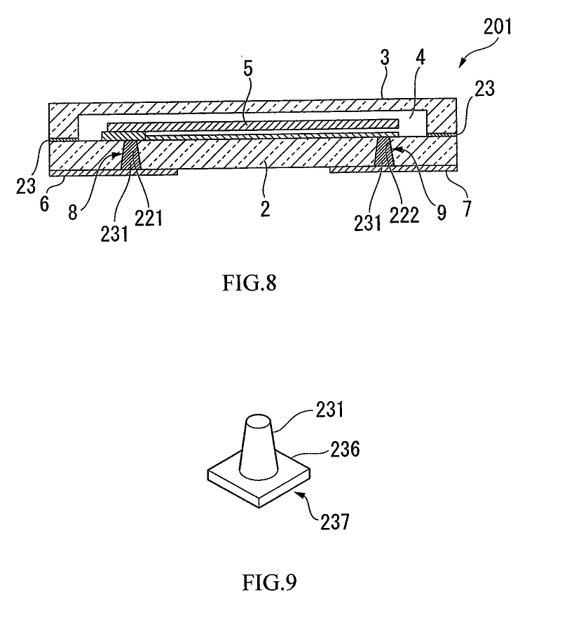

Next, a package manufacturing method according to a second embodiment of the invention will be described based on FIG. 8 to FIG. 12. Members and portions that are the same or similar to those of the above-described first embodiment are denoted with the same reference numerals and a description thereof is omitted. A structure that differs from that of the first embodiment will be described.

As shown in FIG. 8, in a piezoelectric vibrator 201 according to the second embodiment, core portions 231 that become the through electrodes 8, 9 are formed in a truncated cone shape, and inner peripheral surfaces of through holes 221, 222 are tapered surfaces.

As shown in FIG. 9, each of the core portions 231 forms a rivet 237 together with a base portion 236 in a manufacturing process, in a similar manner to the first embodiment.

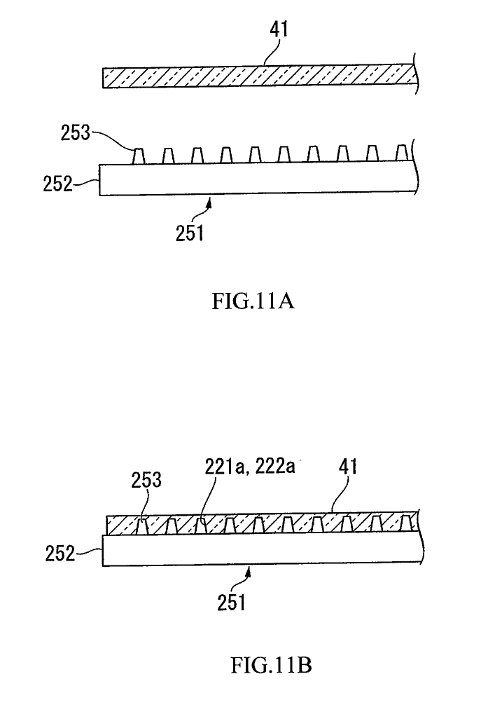

In the manufacturing process, the through holes 221, 222 are first formed in the base substrate wafer 41 as recessed portions (hole portions) 221a, 222a (refer to FIG. 11B). Then, the base substrate wafer 41 on a bottom side of the recessed portions 221a, 222a is polished and removed in a subsequent process, and the through holes 221, 222 become through holes that penetrate the base substrate wafer 41 as shown in FIG. 8.

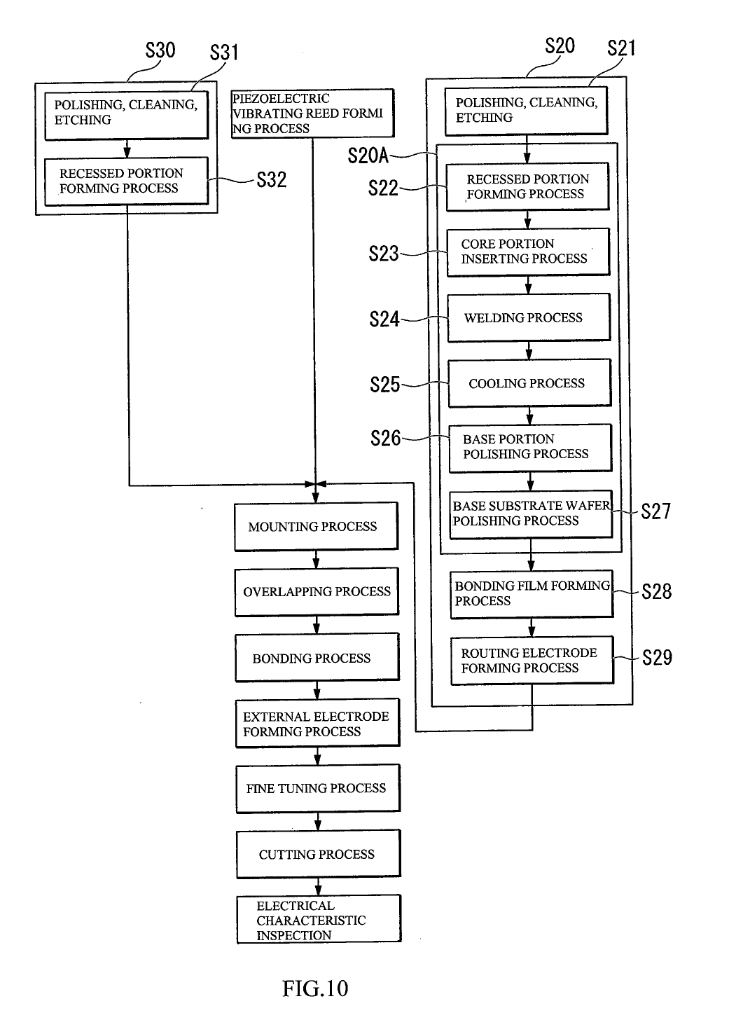

Next, a manufacturing method of the above-described package (the piezoelectric vibrator) will be described with reference to the flowchart shown in FIG. 10.

First, a process that manufactures the base substrate wafer 41, which later becomes the base substrate 2, is performed (S20).

The base substrate wafer 41 is manufactured in a similar manner to the first embodiment (S21), and then a through electrode forming process that forms the through electrodes 8, 9 in the base substrate wafer 41 is performed (S20A).

### (Recessed Portion Forming Process)

First, the recessed portions 221a, 222a are formed in the base substrate wafer 41.

The recessed portions 221a, 222a are formed by heating the base substrate wafer 41 while the base substrate wafer 41 is pressed by a recessed portion forming die (a hole portion forming die) 251 shown in FIG. 11A.

The recessed portion forming die 251 is provided with a flat plate portion 252 and protruding portions 253, in a similar manner to the through hole forming die 51 (refer to FIG. 6A) according to the first embodiment. However, the protruding portions 253 have a truncated cone shape corresponding to the through holes 221, 222, and are formed such that their height is lower than the thickness of the base substrate wafer 41.

As shown in FIG. 11B, in a recessed portion forming process, the base substrate wafer 41 is placed on the recessed portion forming die 251 and pressure is applied in a high temperature state, in a similar manner to the through hole forming process of the first embodiment. At this time, since the protruding portions 253 of the recessed portion forming die 251 do not penetrate the base substrate wafer 41, the recessed portions 221a, 222a are formed in the base substrate wafer 41. The recessed portions 221a, 222a are formed to be larger than the outer shape of the core portions 231, by approximately 20 to 30 μm, for example.

In the second embodiment, since the recessed portion forming die 251, which includes the protruding portions 253 having a truncated cone shape and a lower height, is used, a longer die life is obtained as compared with the through hole forming die 51 of the first embodiment shown in FIG. 6A, which includes the protruding portions 53 having a column shape and a higher height. Note that, since the recessed portions 221a, 222a are formed in a tapered shape, die releasing of the recessed portion forming die 251 is easy in the recessed portion forming process.

The recessed portion forming process can be performed easily as compared with the through hole forming process according to the first embodiment, because there is no need to form the through holes 21, 22 (refer to FIG. 6B) that penetrate the base substrate wafer 41 as in the first embodiment.

### (Core Portion Inserting Process)

Next, a process that inserts the core portions 231 into the recessed portions 221a, 222a is performed (S23).

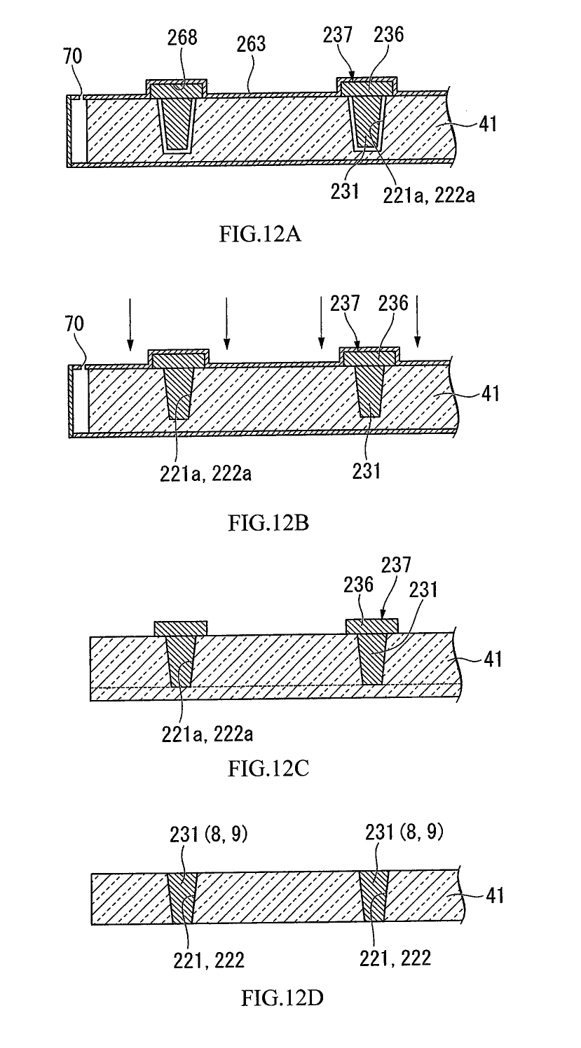

As shown in FIG. 12A, the base substrate wafer 41 is placed such that the recessed portions 221a, 222a are located on an upper surface side, and the core portions 231 are inserted from above so that the base portions 236 are brought into contact with the base substrate wafer 41. At this time, the core portions 231 are easily inserted because the core portions 231 have a truncated cone shape and the recessed portions 221a, 222a are formed with tapered surfaces.

### (Welding Process, Cooling Process)

Next, a process in which the base substrate wafer 41 is welded to the core portions 231 is performed (S24).

A pressurizing die 263 is placed on an upper side of the base substrate wafer 41 in which the rivets 237 are inserted. Pressurizing die recessed portions 268 corresponding to the base portions 236 of the rivets 237 are formed in the pressurizing die 263, and the base portions 236 are inserted into the pressurizing die recessed portions 268. The base portions 236 and bottoms of the pressurizing die recessed portions 268 are not separated from each other, and the base portions 236 are pressed by the pressurizing die 263 at the time of pressurizing in the welding process.

Then, a flat plate-shaped receiving die 262 is placed on the lower side of the base substrate wafer 41 to hold the base substrate wafer 41. The pressurizing die 263 and the receiving die 262 are formed using a similar material to that of the welding die 61 (refer to FIG. 7A and FIG. 7B) according to the first embodiment.

Then, as shown in FIG. 12B, the base substrate wafer 41 is pressurized in the high temperature state in a similar manner to the first embodiment. Thus, the base substrate wafer 41 flows to fill in clearances between the core portions 231 and the recessed portions 221a, 222a, and the base substrate wafer 41 is welded to the core portions 231. Even when one end of each of the core portions 231 is pressed from the pressurizing die 263 side, the other ends are not pressed because they are inserted in the recessed portions 221a, 222a of the base substrate wafer 41. Therefore, it is possible to relieve expansion of the core portions 231 due to heating, and to inhibit deformation or damage of the core portions 231. Further, it is possible to inhibit generation of a crack or chip in the base substrate wafer 41 due to deformation or displacement of the core portions 231.

Next, a process that cools the base substrate wafer 41 is performed in a similar manner to the first embodiment (S25).

### (Base Portion Polishing Process, Base Substrate Wafer Polishing Process)

Next, the base portions 236 of the rivets 237 shown in FIG. 12C are polished and removed in a similar manner to the first embodiment (S26).

Further, before or after the base portion polishing process, the base substrate wafer 41 is polished so that the recessed portions 221a, 222a become through holes (S27).

In a base substrate wafer polishing process, the base substrate wafer 41 on a bottom side of the recessed portions 221a, 222a is polished using a known method. Then, as shown in FIG. 12D, the recessed portions 221a, 222a are penetrated to form the through holes 221, 222, and the ends of the core portions 231 are exposed from the base substrate wafer 41.

Next, processes subsequent to the base substrate polishing process and the base substrate wafer polishing process are performed in a similar manner to the first embodiment, and the package (the piezoelectric vibrator 201) is manufactured.

In the package manufacturing method according to the second embodiment, similar effects to those of the first embodiment are achieved. In the welding process, the base substrate wafer 41 is pressurized in a state in which the core portions 231 are inserted in the recessed portions 221a, 222a. Thus, although the core portions 231 are pressurized from the ends on the pressurizing die 263 side, they are not pressurized from the other ends, and it is therefore possible to inhibit damage of the core portions 231.

Further, since the core portions 231 have a truncated cone shape and the recessed portions 221a, 222a are formed with tapered surfaces, the core portions 231 are easily inserted into the recessed portions 221a, 222a.

Moreover, since the recessed portions 221a, 222a are formed in a tapered shape, die releasing of the recessed portion forming die 251 is easy in the recessed portion forming process.

### Modified Examples

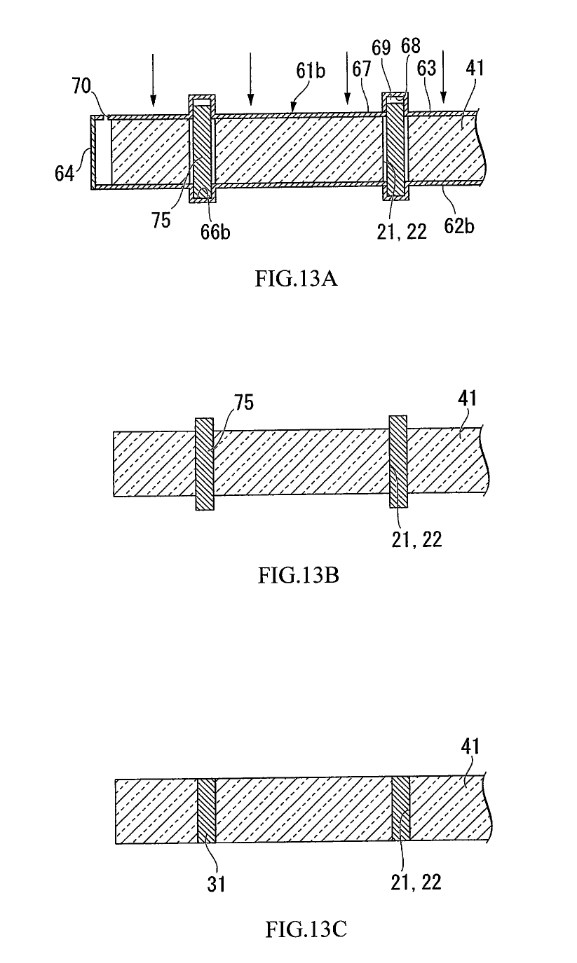

Next, modified examples of the above-described embodiments will be described based on FIG. 13A to FIG. 15. Members and portions that are the same or similar to those of the above-described embodiments are denoted with the same reference numerals and a description thereof is omitted. Structures that differ from those of the embodiments will be described.

As shown in FIG. 13A and FIG. 13B, in a package manufacturing method according to a modified example of the first embodiment, core portions 75 that form the through electrodes 8, 9 are column-shaped metal pins having a thickness thicker than that of the base substrate wafer 41 in a manufacturing process. The core portions 75 are not connected to base portions.

As shown in FIG. 13A, a receiving die 62b that holds the base substrate wafer 41, in which the core portions 75 are inserted in the through holes 21, 22, includes a receiving die flat plate portion 65b and recessed portions 66b corresponding to the tip ends of the core portions 31. After the welding process, tip ends of the core portions 75 protrude from the base substrate wafer 41 as shown in FIG. 13B. The tip ends of the core portions 75 may be polished and removed as shown in FIG. 13C, or may be used as they are.

Note that, in the first embodiment and the modified example of the first embodiment, truncated cone-shaped core portions may be used in place of the column-shaped core portions, and through holes 21, 22 may be formed with tapers.

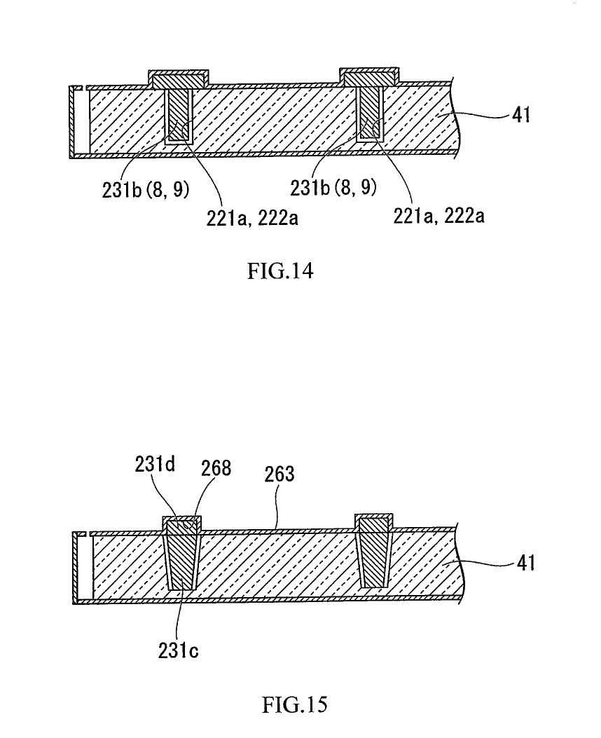

Further, as shown in FIG. 14, in a package manufacturing method according to a modified example of the second embodiment, the recessed portions 221a, 222a of the base substrate wafer 41 are not formed with tapered surfaces and core portions 231b have a column shape. Similarly to the second embodiment, the base substrate wafer 41 on the bottom side of the recessed portions 221a, 222a is polished and removed to form the through electrodes 8, 9.

Further, as shown in FIG. 15, in a package manufacturing method according to another modified example of the second embodiment, core portions 231c are metal pins that are formed in a truncated cone shape.

In this case, the core portions 231c are preferably formed such that ends 231d to be inserted into the pressurizing die recessed portions 268 located at an upper end are formed in a column shape. When the ends 231d are formed in a column shape, clearances are not generated between the pressurizing die recessed portions 268 and the ends 231d of the core portions 231c, as compared with a case in which the entire core portion is formed in a truncated cone shape. Therefore, it is possible to inhibit the core portions 231c from wobbling in the welding process, and at the same time it is possible to inhibit the base substrate wafer 41 from intruding into the clearances between the ends 231d of the core portions 231c and the pressurizing die recessed portions 268.

Note that, in the other modified example of the second embodiment, column-shaped metal pins may be used as the core portions 231c in place of the truncated cone-shaped metal pins.

In these modified examples as well, similar effects to those of the above-described embodiments can be achieved. More specifically, it is possible to ensure stable conductivity between the piezoelectric vibrating reed 5 and the external electrodes 6, 7, as well as stable airtightness in the cavity 4 of the piezoelectric vibrator 1, and it is possible to achieve uniform performance of the piezoelectric vibrator 1.

### (Oscillator)

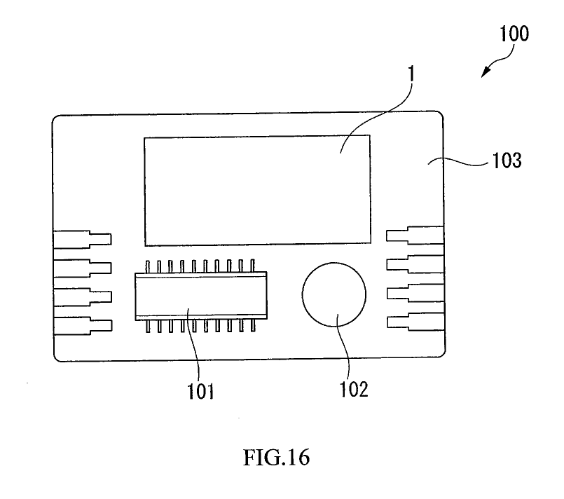

Next, one embodiment of an oscillator according to the invention will be described with reference to FIG. 16.

In an oscillator 100 of the embodiment, the piezoelectric vibrator 1 is formed as an oscillation element that is electrically connected to an integrated circuit 101 as shown in FIG. 16. The oscillator 100 is provided with a substrate 103 on which an electronic component 102 such as a capacitor is mounted. The above-described integrated circuit 101 for the oscillator is mounted on the substrate 103, and the piezoelectric vibrator 1 is mounted in the vicinity of the integrated circuit 101. The electronic component 102, the integrated circuit 101 and the piezoelectric vibrator 1 are respectively and electrically connected by wiring patterns, which are not shown in the drawings. Note that each of the structural components is molded by resin, which is not shown in the drawings.

In the oscillator 100 structured in this manner, when a voltage is applied to the piezoelectric vibrator 1, the piezoelectric vibrating reed 5 in the piezoelectric vibrator 1 vibrates. The vibration is converted to an electrical signal by a piezoelectric property of the piezoelectric vibrating reed 5, and input to the integrated circuit 101 as an electrical signal. The input electrical signal is subjected to various types of processing by the integrated circuit 101 and is output as a frequency signal. Thus, the piezoelectric vibrator 1 functions as an oscillation element.

Further, by selectively setting the structure of the integrated circuit 101, for example, to an RTC (real time clock) module or the like in response to demand, in addition to a single-function oscillator for a timepiece and the like, it is possible to add a function of controlling an operation date or time of the device or an external device or a function of providing time or a calendar.

As described above, the oscillator 100 of the embodiment is provided with the high quality piezoelectric vibrator 1 in which airtightness in the cavity 4 is reliable, conductivity between the piezoelectric vibrating reed 5 and the external electrodes 6, 7 is stably ensured, and operation reliability is improved. Therefore, it is also possible to similarly improve the quality of the oscillator 100 itself such that conductivity is stably ensured and operation reliability is improved. In addition to this, stable and highly accurate frequency signals can be obtained over a long period of time.

### (Electronic Device)

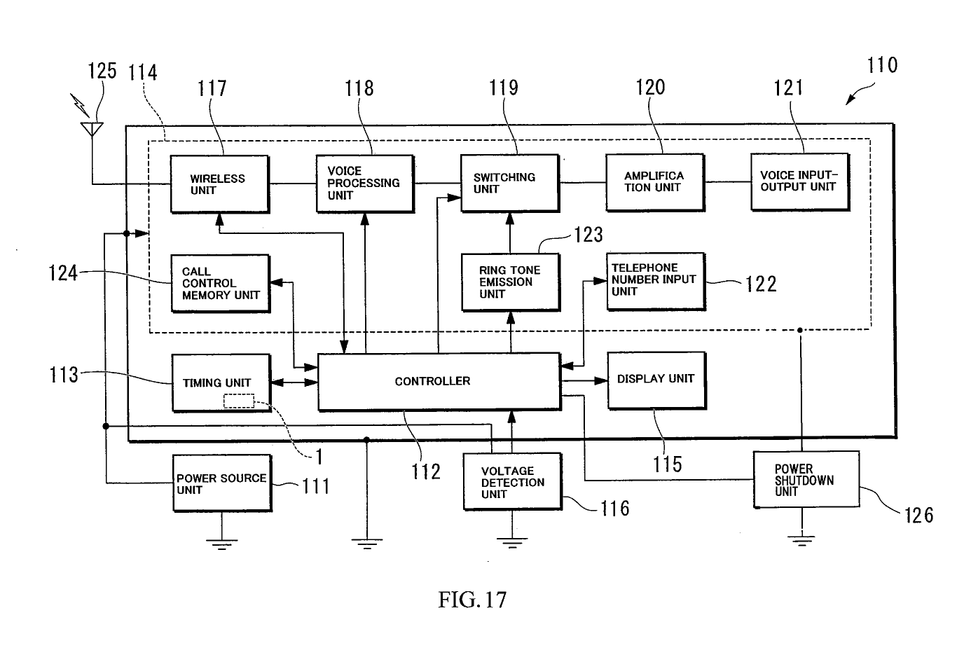

Next, one embodiment of an electronic device according to the invention will be described with reference to FIG. 17. Note that a portable information device 110 having the above-described piezoelectric vibrator 1 will be described as an example of the electronic device.

First, the portable information device 110 according to the embodiment is represented by a mobile phone, for example, and is made by developing and improving a wrist watch in related art. The external appearance is similar to the wrist watch, and a liquid crystal display is arranged in a section corresponding to a dial plate so that current time and the like can be displayed on its screen. When being used as a communication device, it can be removed from the wrist, and communication similar to a mobile phone of related art can be performed using a speaker and a microphone incorporated in an inner side section of a band. However, as compared to the mobile phone of the related art, it is dramatically compact and lightweight.

Next, the structure of the portable information device 110 of the embodiment will be described. As shown in FIG. 17, the portable information device 110 is provided with the piezoelectric vibrator 1 and a power supply portion 111 to supply electric power. The power supply portion 111 is formed by a lithium secondary battery, for example. A control portion 112 that performs various types of control, a time measuring portion 113 that counts time etc., a communication portion 114 that performs communication with the outside, a display portion 115 that displays various types of information, and a voltage detection portion 116 that detects a voltage of each of the functional portions are connected in parallel to the power supply portion 111. Electric power is supplied to each of the functional portions by the power supply portion 111.

The control portion 112 controls each of the functional portions and thereby performs operation control of the entire system, such as transmission and reception of audio data, measurement and display of current time, and the like. Further, the control portion 112 is provided with a ROM into which a program is written in advance, a CPU that reads and executes the program written into the ROM, a RAM that is used as a work area of the CPU, and the like.

The time measuring portion 113 is provided with an integrated circuit that incorporates an oscillation circuit, a register circuit, a counter circuit and an interface circuit etc., and the piezoelectric vibrator 1. When a voltage is applied to the piezoelectric vibrator 1, the piezoelectric vibrating reed 5 vibrates. The vibration is converted to an electrical signal due to piezoelectric property of crystal, and is input to the oscillation circuit as the electrical signal. The output of the oscillation circuit is binarized and measured by the register circuit and the counter circuit. Then, signal transmission and reception with the control portion 112 is performed via the interface circuit, and current time, current date or calendar information etc. is displayed on the display portion 115.

The communication portion 114 has similar functions to those of the mobile phone of the related art, and is provided with a wireless portion 117, an audio processing portion 118, a switching portion 119, an amplifier portion 120, an audio input/output portion 121, a telephone number input portion 122, a ring tone generation portion 123 and a call control memory portion 124.

The wireless portion 117 carries out transmission and reception of various types of data, such as audio data, with a base station via an antenna 125. The audio processing portion 118 encodes and decodes an audio signal input from the wireless portion 117 or the amplifier portion 120. The amplifier portion 120 amplifies a signal input from the audio processing portion 118 or the audio input/output portion 121 to a predetermined level. The audio input/output portion 121 is formed by a speaker, a microphone and the like, and makes a ring tone and incoming audio louder and collects audio.

The ring tone generation portion 123 generates a ring tone in response to a call from the base station. The switching portion 119 switches the amplifier portion 120 connected to the audio processing portion 118 to the ring tone generation portion 123 only when a call arrives, so that the ring tone generated in the ring tone generation portion 123 is output to the audio input/output portion 121 via the amplifier portion 120.

Note that the call control memory portion 124 stores a program relating to incoming and outgoing call control for communications. The telephone number input portion 122 includes, for example, numeric keys from 0 to 9 and other keys and the telephone number of a call destination is input by depressing these numeric keys and the like.

The voltage detection portion 116 detects a voltage drop and notifies the control portion 112 of it when a voltage applied by the power supply portion 111 to each of the functional portions, such as the control portion 112, drops below a predetermined value. The predetermined voltage value in this case is a value pre-set as the lowest voltage necessary to operate the communication portion 114 stably, and is, for example, about 3V. When receiving a notification of the voltage drop from the voltage detection portion 116, the control portion 112 disables operations of the wireless portion 117, the audio processing portion 118, the switching portion 119 and the ring tone generation portion 123. In particular, it is essential to stop the operation of the wireless portion 117 that consumes a large amount of electric power. Furthermore, a message informing that the communication portion 114 is unavailable due to insufficient battery power is displayed on the display portion 115.

More specifically, it is possible to disable the operation of the communication portion 114 by the voltage detection portion 116 and the control portion 112, and to display the notification message on the display portion 115. Although a character message may be used for this display, an x (cross) mark may be put on a telephone icon displayed on an upper section of a display screen of the display portion 115, as a more intuitive display.

Note that, by providing a power supply shutdown portion 126 that is capable of selectively shutting down the power supply to portions involved with the function of the communication portion 114, it is possible to stop the function of the communication portion 114 in a more reliable manner.

As described above, the portable information device 110 of the embodiment is provided with the high quality piezoelectric vibrator 1 in which airtightness in the cavity 4 is reliable, conductivity between the piezoelectric vibrating reed 5 and the external electrodes 6, 7 is stably ensured, and operation reliability is improved. Therefore, it is also possible to similarly improve the quality of the portable information device itself such that conductivity is stably ensured and operation reliability is improved. In addition to this, it is possible to display stable and highly accurate timepiece information over a long period of time.

### (Radio Timepiece)

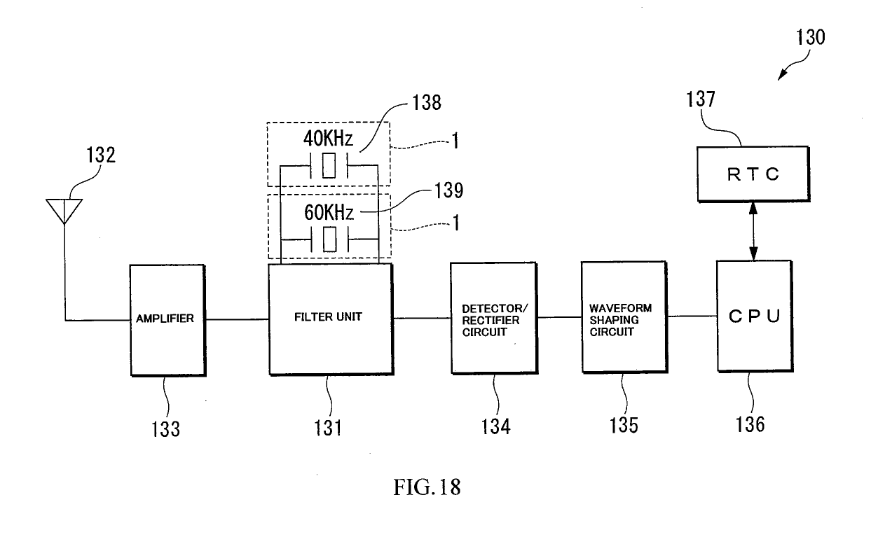

Next, one embodiment of a radio timepiece according to the invention will be described with reference to FIG. 18.

A radio timepiece 130 of the embodiment is provided with the piezoelectric vibrator 1 that is electrically connected to a filter portion 131 as shown in FIG. 18, and is a timepiece that has a function of receiving a standard wave including timepiece information, and a function of automatically correcting the standard wave to a correct time and displaying it.

In Japan, transmitting stations (transmitter stations) for transmitting standard waves are located in Fukushima prefecture (40 kHz) and Saga prefecture (60 kHz), and transmit standard waves, respectively. A long wave corresponding to 40 kHz or 60 kHz has a property of propagating on the ground surface and also has a property of propagating while being reflected by an ionized layer and the ground surface. Accordingly, the propagation range is wide and the above-mentioned two transmitting stations cover the entire area of Japan.

Hereinafter, a functional structure of the radio timepiece 130 will be described in detail.

An antenna 132 receives a standard wave that is a long wave of 40 kHz or 60 kHz. The standard wave, which is a long wave, is a wave that is obtained by performing AM modulation of time information, which is called a time code, on a carrier wave of 40 kHz or 60 kHz. The received standard wave, which is a long wave, is amplified by an amplifier 133, and is filtered and tuned by the filter portion 131 having a plurality of the piezoelectric vibrators 1.

The piezoelectric vibrators 1 of the embodiment are respectively provided with crystal oscillator portions 138, 139 having resonance frequencies of 40 kHz and 60 kHz, which are the same as the above-described carrier frequencies.

Further, the filtered signal with a predetermined frequency is detected and demodulated by a detection and rectification circuit 134. Then, the time code is taken out through a waveform shaping circuit 135 and is counted by a CPU 136. The CPU 136 reads information of a current year, cumulative days, a day of the week, a time of day, and the like. The read information is reflected on an RTC 137 and correct time information is displayed.

Since the carrier wave is 40 kHz or 60 kHz, the above-described oscillator having a tuning-fork type structure is preferably used as the crystal oscillator portions 138, 139.

Note that, although the above-described explanation is made using an example in Japan, the frequencies of long wave standard waves are different in overseas countries. For example, the standard wave with a frequency of 77.5 KHz is used in Germany. Accordingly, when the radio timepiece 130 that is also compatible in overseas countries is incorporated into a portable device, the piezoelectric vibrator 1 having a frequency different from the frequency used in Japan is further necessary.

As described above, the radio timepiece 130 of the embodiment is provided with the high quality piezoelectric vibrator 1 in which airtightness in the cavity 4 is reliable, conductivity between the piezoelectric vibrating reed 5 and the external electrodes 6, 7 is stably ensured, and operation reliability is improved. Therefore, it is also possible to similarly improve the quality of the radio timepiece itself such that conductivity is stably ensured and operation reliability is improved. In addition to this, it is possible to count time stably and highly accurately over a long period of time.

Hereinabove, the embodiments of the package manufacturing method according to the invention are described. However, the invention is not limited to the above-described embodiments, and modifications are possible as appropriate within a scope that does not depart from the spirit of the invention.

In the above-described first embodiment, the through holes 21, 22 are formed by the through hole forming die 51 being pressed against the base substrate wafer 41 and the base substrate wafer 41 being heated. However, instead, a sandblasting method etc. may be used to form the through holes 21, 22 in the base substrate wafer 41.

Further, in the above-described second embodiment, the recessed portions 221a, 222a are formed by the recessed portion forming die 251 being pressed against the base substrate wafer 41 and the base substrate wafer 41 being heated. However, instead, the sandblasting method etc. may be used to form the recessed portions 221a, 222a in the base substrate wafer 41.

The base substrate wafer 41 is welded to the core portions 31 and no recessed portions are generated in the base substrate wafer 41 around the through electrodes 8, 9. Therefore, it is possible to ensure stable airtightness in the cavity 4 of the piezoelectric vibrator 1, as well as stable conductivity between the piezoelectric vibrating reed 5 and the external electrodes 6, 7, and it is possible to achieve uniform performance of the piezoelectric vibrator 1.

What is claimed is:

1. A manufacturing method of a package including a plurality of substrates that are bonded to each other, a cavity that is formed inside the plurality of substrates, and through electrodes that conduct current between the inside of the cavity and the outside of the plurality of substrates, the through electrodes each being formed such that a conductive core portion made of a metal material is arranged in a hole portion of a through electrode forming substrate made of a glass material, the manufacturing method being characterized by comprising:
a hole portion forming step of forming the hole portion, into which the core portion is inserted, in a through electrode forming substrate wafer;
a core portion inserting step of inserting the core portion into the hole portion formed in the through electrode forming substrate wafer;
a welding step of heating the through electrode forming substrate wafer and welding it to the core portion; and
a cooling step of cooling the through electrode forming substrate wafer,
wherein
in the welding step, the through electrode forming substrate wafer is welded to the core portion by heating the through electrode forming substrate wafer to a temperature higher than a softening point of the glass material while a pressurizing die is placed on a surface of the through electrode forming substrate wafer and the through electrode forming substrate wafer is pressed by the pressurizing die.

2. The manufacturing method of the package according to claim 1, wherein
in the cooling step, a cooling rate from a strain point of the glass material that forms the through electrode forming substrate wafer plus fifty degrees Celsius to the strain point minus fifty degrees Celsius is made slower than a cooling rate from a heating temperature of the welding step to the strain point plus fifty degrees Celsius.

3. The manufacturing method of the package according to claim 1, wherein
in the hole portion forming step, a through hole is formed as the hole portion, the pressurizing die has a recessed portion into which an upper end of the core portion can be inserted, and a bottom of the recessed portion is formed to be separated from the upper end of the core portion when the through electrode forming substrate wafer is pressed by the pressurizing die.

4. The manufacturing method of the package according to claim 1, wherein
the pressurizing die is formed of a material whose main component is one of carbon, aluminium oxide, zirconia, boron nitride and silicon nitride.

5. The manufacturing method of the package according to claim 1, wherein
in the hole portion forming step, the hole portion is formed by heating the through electrode forming substrate wafer while the through electrode forming substrate wafer is pressed by a hole portion forming die that is made of a carbon material and that has a protruding portion corresponding to the hole portion.

6. The manufacturing method of the package according to claim 1, wherein
in the core portion inserting step, the core portion of a conductive rivet, which has a flat plate-shaped base portion and the core portion that stands on a surface of the base portion, is inserted into the hole portion formed in the through electrode forming substrate wafer, and the base portion of the rivet is caused to come into contact with the through electrode forming substrate wafer, and
after the cooling step, the base portion of the rivet is polished and removed.

7. The manufacturing method of the package according to claim 1, wherein
the core portion is formed in a truncated cone shape, and in the hole portion forming step, an inner peripheral surface of the hole portion is formed in a tapered shape.

8. The manufacturing method of the package according to claim 1, wherein
in the hole portion forming step, the hole portion is formed in the through electrode forming substrate wafer as a recessed portion, and
after the cooling step, the through electrode forming substrate wafer on a bottom side of the recessed portion is polished and the core portion is exposed.

9. A piezoelectric vibrator manufacturing method, comprising the steps of:
performing the manufacturing method of the package according to claim 1; and
disposing a piezoelectric vibrating reed inside the cavity while the piezoelectric vibrating reed is mounted on the through electrodes.

10. An oscillator, wherein
a piezoelectric vibrator manufactured by the method according to claim 9 is electrically connected to an integrated circuit, as an oscillation element.

11. An electronic device, wherein
a piezoelectric vibrator manufactured by the method according to claim 9 is electrically connected to a time measuring portion.

12. A radio timepiece, wherein
a piezoelectric vibrator manufactured by the method according to claim 9 is electrically connected to a filter portion.
